(19) United States
(12) Patent Application Publication
(10) Pub. No.: US 2006/0216868 A1
(43) Pub. Date: Sep. 28, 2006

(54) Package structure and fabrication thereof

(75) Inventors: Jun-Young Yang, Kaohsiung (TW); You-Ock Joo, Kaohsiung (TW); Chang-Kyu Ahn, Kaohsiung (TW); Jung-Tae Kim, Kaohsiung (TW); Sung-Sig Kang, Kaohsiung (TW)

Correspondence Address: GENUS LAW GROUP, 5543 TALON COURT, FAIRFAX, VA, 22032, US

(73) Assignee: ADVANCED SEMICONDUCTOR ENGINEERING INC.

(21) Appl. No.: 11/088,773

(22) Filed: Mar. 25, 2005

(51) Int. Cl. H01L 21/00

(52) U.S. Cl. 438/125; 438/126

(57) ABSTRACT

The fabrication and device of package structure with a plurality of conductive contacts are provided herein. At least one chip is attached among the conductive pads on the surface of a wafer. A number of conductive wires are attached on the conductive pads and encapsulated by a layer. The layer is removed from the top thereof until to expose the conductive contacts derived from the conductive wires.

### BACKGROUND OF THE INVENTION

1. Field of the Invention

The present invention generally relates to a package device and fabrication thereof, and more particularly to a package device without a substrate and fabrication thereof.

2. Description of the Prior Art

On these days, the markets of portable and communication electrics have been mature. On the ground of reason aforementioned, it is necessary to for package structure to be simple and low-cost assembled with lighter and thinner volume and higher density and integrity.

Generally speaking, the package structure of an electronic instrument includes electronic devices, connecting structure, molding portion and a substrate. The substrate is a typical printed circuit board for electrical connection and redistribution. Thus, it is necessary for an electronic device with high-density integrity, such as a chip with more connecting ends, to have the substrate for the purpose of redistribution and supporting.

However, for portable instruments, the electronic devices or packages require more compact volume and lighter weight, as well as lower cost on fabrication and material consumption. Thus, it is necessary to develop non-typical configuration of package structure or improve the on-going package configuration to meet market requirements and improve device requirement.

### SUMMARY OF THE INVENTION

It is one of features of the present invention to provide a package structure and the fabrication thereof. A conductive contact attached and exposed by a layer of encapsulation is applied to a package structure make the package structure thinner and lighter.

It is another one of features of the present invention to provide a package structure and the fabrication thereof with more simple process and lower cost. Without the utilization of a substrate, a conductive contact for exterior connection of a package structure is directly fabricated on a wafer structure.

It is another one of features of the present invention is to provide a CSP structure and the fabrication thereof. With molding compound to encapsulate conductive wires, the CSP structure is assembled with lighter and thinner volume to improve signal propagation characteristics.

According to the aspects of the present invention, one embodiment of the present invention provides the fabrication of package structure with a plurality of conductive contacts. A chip is attached among the conductive pads on the surface of a wafer. A plurality of conductive wires are formed on the conductive pads and encapsulated by a layer. Then the portion of the layer is removed to expose the plurality of conductive contacts derived from the conductive wires.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A-1F are schematic cross-sectional diagrams illustrating the structure and the manufacture of an embodiment of package structure in accordance with the present invention;

FIG. 1G is a schematic cross-sectional diagram illustrating the individual package unit sawed from the wafer level package in accordance with the present invention;

FIG. 1H is a schematic cross-sectional diagram illustrating the individual package unit with solder balls in accordance with the present invention;

FIG. 2 illustrates a schematic top-view diagram for the individual semiconductor device 16 with package structure thereof;

FIGS. 3A-3C schematic cross-sectional diagrams illustrating the structure and the manufacture of another embodiment of package structure in accordance with the present invention;

FIG. 4 is a schematic cross-sectional diagram illustrating the third embodiment in accordance with the present invention; and

FIG. 5 is a schematic top-view diagram of FIG. 4.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

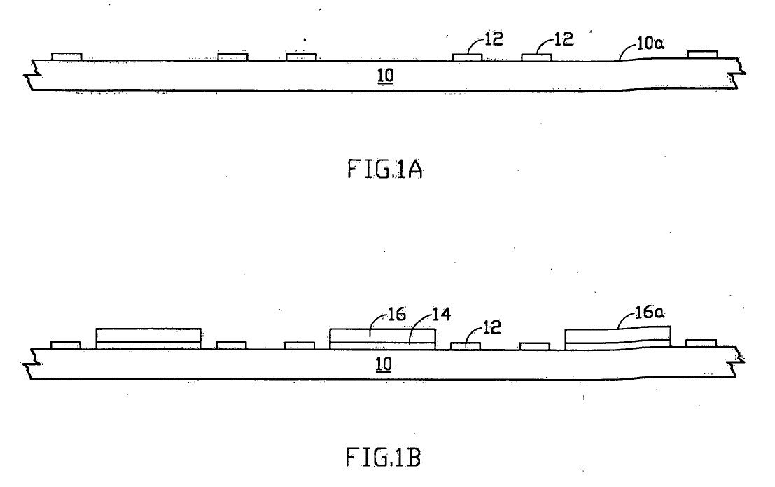

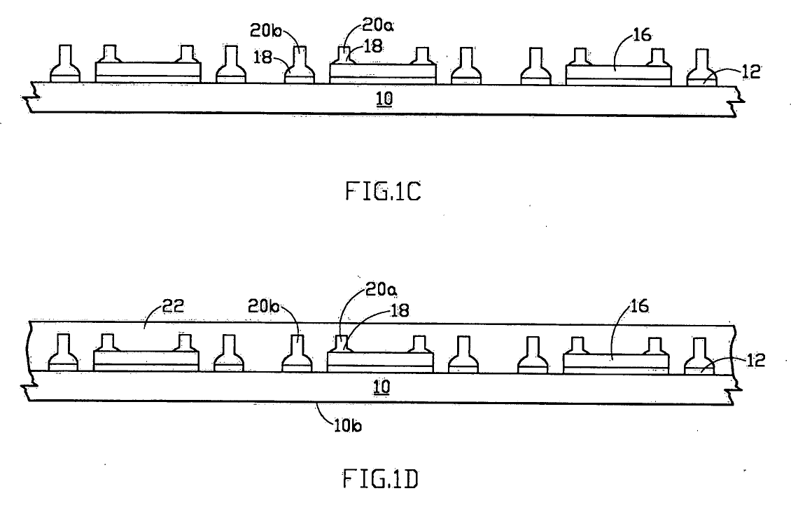

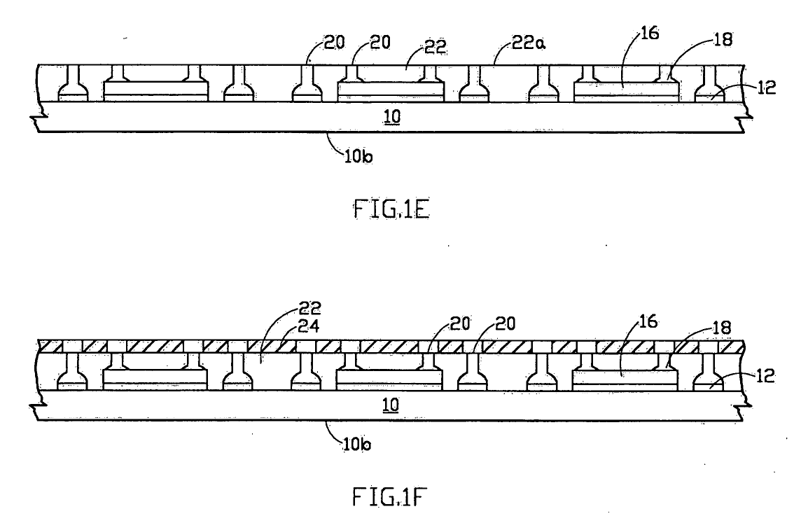

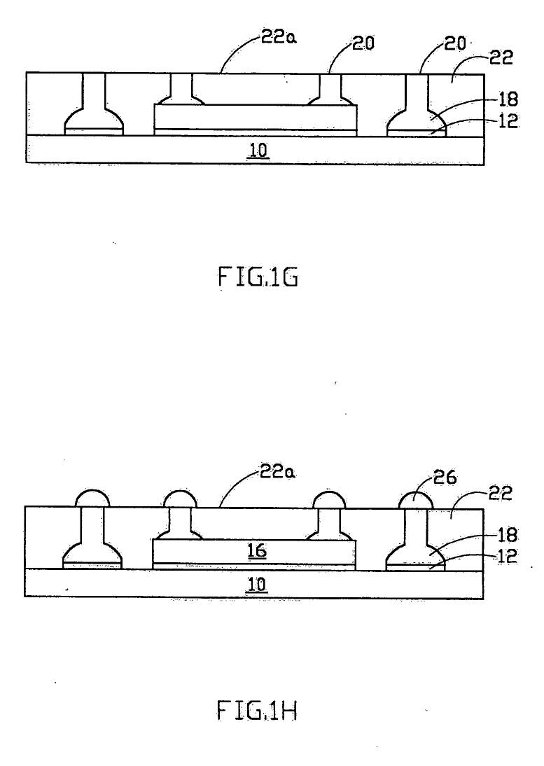

FIGS. 1A-1F are schematic cross-sectional diagrams illustrating the structure and the manufacture of an embodiment of package structure in accordance with the present invention. Depicted in FIG. 1A, a number of conductive pads 12 are patterned on the active side 10a of a wafer 10 by any suitable method. In one embodiment, the wafer 10 may be a silicon substrate or wafer in which some devices, chips or structures are done. The conductive pads 12, such as aluminum or copper pads, are formed or patterned on the active side 10a.

Next, shown in FIG. 1B, an adhesive film 14 is employed among the conductive pads 12 and semiconductor devices 16 are subsequently applied on the adhesive film 14, individually. In one embodiment, the adhesive film 14, such as epoxy insulative film, is printed on the active side 10a. The semiconductor devices 16, such as semiconductor bare die or chip, are attached to the active side 10a with the adhesive film 14. Furthermore, a number of conductive pads (not shown) may be predetermined patterned on the surface 16a of each of the semiconductor devices 16. It is noted that at least one semiconductor device 16 is corresponding to or aligned one beneath device of the wafer 10.

Depicted on FIG. 1C, a conductive wire is formed on each conductive pad of the semiconductor devices 16 and each conductive pad 12. In one embodiment, but not limited to, some conductive studs 18, such as gold stud, are first applied to the surface 16a and the active side 10a and then lifted to form each conductive wire 20a on the surface 16a and conductive wire 20b on each conductive pad 12. It is understandable that the heights of the conductive wire 20a or conductive wire 20b are adjustable to reach an identical level.

Next, shown in FIG. 1D, an encapsulation 22 covers over the surface 16a and active side 10a to encapsulate the semiconductor devices 16, conductive studs 18, conductive wire 20a and conductive wire 20b. In one embodiment, the encapsulation 22, such as a polymer compound, is molded over the surface 16a and active side 10a to encapsulate the semiconductor devices 16, conductive studs 18, conductive wire 20a and conductive wire 20b. In other words, the conductive wire 20a and conductive wire 20b sink in the encapsulation 22. Alternatively, the encapsulation 22, such as dielectric layer, is deposited over the surface 16a and active side 10a to encapsulate the semiconductor devices 16, conductive studs 18, conductive wire 20a and conductive wire 20b. It is noted that the backside 10b of the wafer 10 is exposed outside of the encapsulation 22.

Depicted on FIG. 1E, the encapsulation 22 is removed from a top thereof until the ends of the conductive wire 20a and conductive wire 20b are exposed to form conductive contacts 20 on the surface 22a of the encapsulation 22. In one embodiment, the encapsulation 22 is removed by grinding, such as removed by a chemical mechanical polishing. Alternatively, the encapsulation 22 is removed by etching. Optionally, a backside 10b of the wafer 10 opposite to the active side 10a may be moved for thinning the wafer 10 by any suitable method.

Optionally, depicted in FIG. 1F, for a wafer-level process, a mask layer 24 is formed over the surface 22a and the conductive contacts 20 and then opened to expose the encapsulation 22 for subsequent solder formation. It is noted that the backside 10b of the wafer is exposed without any shield.

Optionally, a singulation process, such as a sawing process is employed the whole structure to divide the semiconductor device 16 into individual unit with corresponding package structure thereof, shown in FIG. 1G. Alternatively, the thinning process may be employed the individual unit with the package structure thereof.

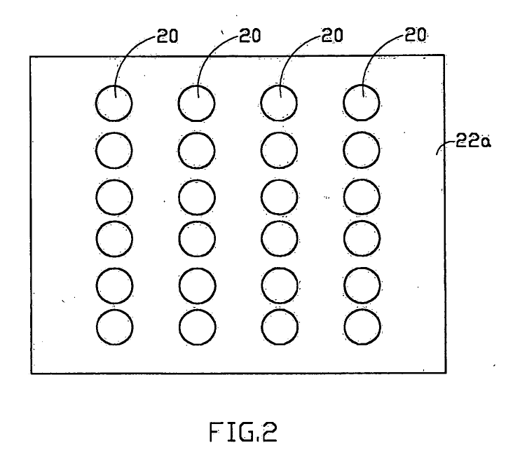

After the complement of the individual semiconductor device 16, a solder ball 26 may be formed on each conductive contact 20, shown in FIG. 1H, for example, applied on a BGA type product. In one embodiment, the solder balls 26 are implemented by printing a plurality of solder paste on each exposed conductive contact 20 through a plurality of holes within a stencil and then employing a reflow process to form solder balls. In another embodiment, the solder balls 26 would be implemented by printing, mounting conductive balls and then employing a reflow process. Alternatively, the exposed conductive contacts 20 may be utilized directly, regardless of the formation of solder balls, for example, applied on a LGA type product. FIG. 2 illustrates a schematic top-view diagram for the individual semiconductor device 16 with package structure thereof. The conductive contacts 20 derived from conductive wire 20a and conductive wire 20b are exposed on the surface 22a of the conductive contacts 20. Alternatively, the solder balls 26 are on the surface 22a of the conductive contacts 20. Thus, the exposed conductive contacts 20 are directly utilized for electrically contacting exterior devices or structures.

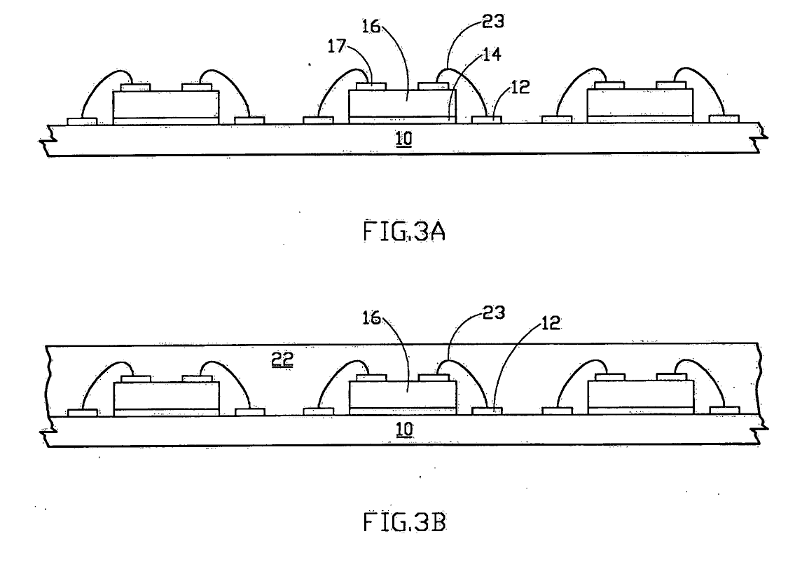

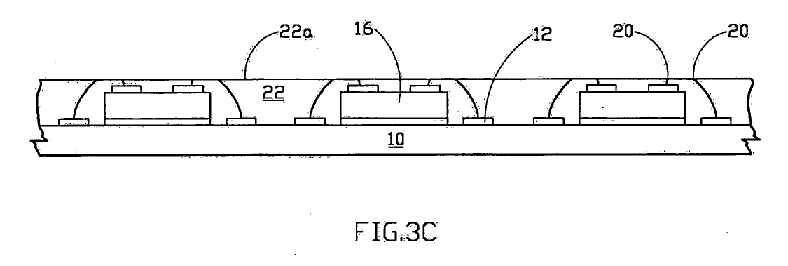

FIGS. 3A-3C are schematic cross-sectional diagrams illustrating the structure and the manufacture of another embodiment of package structure in accordance with the present invention. Similarly, the semiconductor devices 16 are attached to the active side 10a via the adhesive film 14 by suitable methods aforementioned. A number of conductive pads 17, such as aluminum or copper pads, are distributed on the surface 16a of the semiconductor device 16. Next, the conductive wires 23 are formed on the conductive pads 12 and the conductive pads 17. Different from the first embodiment aforementioned, each conductive wire 23 further connects each conductive pad 17 and the corresponding conductive pad 12. In the embodiment, each conductive wire 23 is bonded on each conductive pad 17 and the corresponding conductive pad 12 by wiring method.

Depicted on FIG. 3B the encapsulation 22 covers over the active side 10a and surface 16a to encapsulate the semiconductor devices 16, the conductive wires 23 and the active side 10a. In the embodiment, each conductive wire 23 with an arc top is overwhelmed by the encapsulation 22. Next, the encapsulation 22 is removed from a top thereof until the arc portion of each conductive wire 23 is cut to divide two parts, shown in FIG. 3C. Each part has one exposed end to form the conductive contacts 20 and the other sunken end attached to the conductive pads 17 or the conductive pad 12. Thus, the conductive contacts 20 are exposed on the surface 22a of the encapsulation 22 as exterior contact terminals. Optionally, the wafer 10 may be thinned from the backside 10b thereof. It is understandable that subsequent process or other steps not mentioned herein are similar to the first embodiment aforementioned.

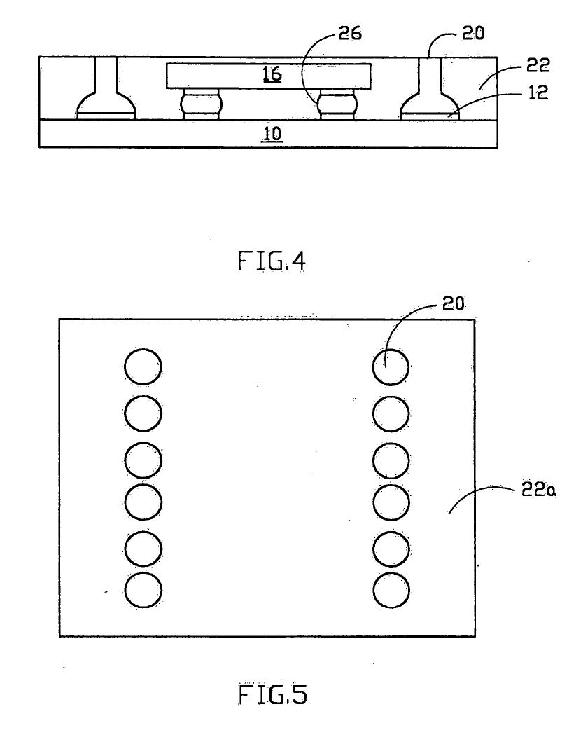

FIG. 4 is a schematic cross-sectional diagram illustrating the third embodiment in accordance with the present invention. In the third embodiment, the semiconductor device 16 is a flip chip and attached to the wafer 10 via a number of solder balls 26. Accordingly, all of the conductive contacts 20 exposed on the surface 22a are directly attached to the conductive pad 12 on the active side 10a of the wafer 10. A schematic top-view diagram of FIG. 4 is shown in FIG. 5. The exposed conductive contacts 20 are distributed beside the semiconductor devices 16 beneath the encapsulation 22.

Without the application of a substrate to the package structure, a lighter, thinner package with higher density integrity is achieved according to the aspects of the present invention. Furthermore, high density wafer level CSP and low-cost and simple fabrication method thereof are also achieved according to the aspects of the present invention. Accordingly, a flip chip, stacking or other types chips are applied to the package structure. Thus, end products such as EPROM, flash memory, DRAM, integrated passive networks, USB port, memory card, MMC (Multi Media Card), mobile phones, PDAs, laptop PCs, disk drives, digital cameras, MP3 players, GPS navigation devices and other portable products are implemented by the package structure according to the aspects of the present invention.

Accordingly, one of embodiments of the present invention provides a formation of package structure with a plurality of conductive contacts. A wafer is with a plurality of first conductive pads on an active side. A number of semiconductor devices are attached among the first conductive pads. A number of conductive wires are formed on the first conductive pads and the second conductive pads of each semiconductor device. An encapsulation encapsulates the semiconductor devices, conductive wires and wafer. A portion of the layer is removed to expose the conductive contacts derived from the conductive wires.

Accordingly, one of embodiments of the present invention provides a package structure with a plurality of conductive contacts thereon. A wafer is with a number of conductive pads on an active side. A semiconductor device is among the conductive pads and attached on the surface. An encapsulation covers over the semiconductor device and surface. A number of conductive wires are in the encapsulation, contact the conductive pads and have a number of conductive contacts exposed to the encapsulation.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

1. A fabrication of package structure with a plurality of conductive contacts, comprising:
providing a wafer with a plurality of first conductive pads on an first active side;
attaching a chip among said first conductive pads on said first active side;
forming a plurality of conductive wires on said first conductive pads;
forming an encapsulation covering said chip, said conductive wires and said wafer; and
removing a portion of said encapsulation to expose said plurality of conductive contacts, wherein said conductive contacts are derived from said conductive wires.

2. The fabrication of package structure with a plurality of conductive contacts in accordance with the claim 1, wherein said forming step further comprises forming a portion of said conductive wires on a plurality of second conductive pads on a second active side of said chip.

3. The fabrication of package structure with a plurality of conductive contacts in accordance with the claim 2, wherein said attaching step comprises providing an adhesive film between said chip and said first active side.

4. The fabrication of package structure with a plurality of conductive contacts in accordance with the claim 1, wherein said forming step further comprises bonding said conductive wires connecting first conductive pads and a plurality of second conductive pads on a second active side of said chip.

5. The fabrication of package structure with a plurality of conductive contacts in accordance with the claim 1, wherein said attaching step comprises forming a plurality of solder balls between a second active side of said chip and said first active side of said wafer.

6. The fabrication of package structure with a plurality of conductive contacts in accordance with the claim 1, further comprising thinning a portion of said wafer from a backside of said wafer opposite to said first active side.

7. The fabrication of package structure with a plurality of conductive contacts in accordance with the claim 1, further comprising forming a conductive ball on each said exposed conductive contact.

8. The fabrication of package structure with a plurality of conductive contacts in accordance with the claim 1, wherein the step of forming said encapsulation comprises forming a molding compound by transfer mold.

9. The fabrication of package structure with a plurality of conductive contacts in accordance with the claim 1, further comprising singulating said wafer into a plurality of individual units after said removing step.

10. A fabrication of stack package structure with a plurality of conductive contacts, comprising:
providing a first semiconductor device with a plurality of first conductive pads on an active side of said first semiconductor device;
attaching a second semiconductor device among said first conductive pads on said first semiconductor device, wherein said second semiconductor device is with a plurality of second conductive pads thereon;
forming a plurality of conductive wires on said first conductive pads and said second conductive pads;
forming an encapsulation covering said second semiconductor device, said conductive wires and said active side of said first semiconductor device, wherein a backside of said first semiconductor device is exposed outside of said encapsulation; and
removing a portion of said encapsulation to expose said plurality of conductive contacts, wherein said conductive contacts are derived from said conductive wires.

11. The fabrication of package structure with a plurality of conductive contacts in accordance with the claim 10, wherein said forming step comprises bonding said conductive wires connecting said first conductive pads and said second conductive pads and removing step comprises disconnecting said first conductive pads and said second conductive pads.

12. The fabrication of package structure with a plurality of conductive contacts in accordance with the claim 10, wherein said forming step comprises:
forming a gold stud on each said first conductive pad and each said second conductive pad; and
lifting said gold stud to form each said conductive wire.

13. The fabrication of package structure with a plurality of conductive contacts in accordance with the claim 10, her comprising grinding a portion of said first semiconductor device from said backside opposite to said active side.

14. The fabrication of package structure with a plurality of conductive contacts in accordance with the claim 10, further comprising forming a conductive ball on each said exposed conductive contact.

15. A package structure with a plurality of conductive contacts thereon, said package structure comprising:
a first semiconductor device with a plurality of first conductive pads on an active side;
a second semiconductor device among said first conductive pads and attached on said active side;
an encapsulation over said second semiconductor device and said active side; and
a plurality of conductive wires in said encapsulation and contacting said first conductive pads, wherein said conductive wires have said conductive contacts exposed on said encapsulation.

16. The package structure with a plurality of conductive contacts thereon in accordance with the claim 15, wherein said second semiconductor device has a plurality of second conductive pads contacting said conductive wires.

17. The package structure with a plurality of conductive contacts thereon in accordance with the claim 15, wherein each said conductive wire comprises a conductive stud and a lifting portion from said conductive stud.

18. The package structure with a plurality of conductive contacts thereon in accordance with the claim 15, further comprising a plurality of solder balls attaching said second semiconductor device to said active side of said first semiconductor device.

19. (canceled)

20. The package structure with a plurality of conductive contacts thereon in accordance with the claim 15, wherein said encapsulation comprises a molding compound.

21. The package structure with a plurality of conductive contacts thereon in accordance with the claim 15, further comprising a solder ball on each said conductive contact.
